(19) United States
(12) Patent Application Publication
(10) Pub. No.: US 2011/0043268 A1
(43) Pub. Date: Feb. 24, 2011

(54) LEVEL SHIFTER WITH NATIVE DEVICE

(75) Inventor: HOU-YING HUANG, Keelung City (TW)

Correspondence Address: J C PATENTS, 4 VENTURE, SUITE 250, IRVINE, CA, 92618, US

(73) Assignee: United Microelectronics Corp., Hsinchu (TW)

(21) Appl. No.: 12/546,276

(22) Filed: Aug. 24, 2009

(51) Int. Cl. H03L 5/00

(52) U.S. Cl. 327/333

(57) ABSTRACT

A level shifter includes an inverter, a first native device, a second native device, a first transistor, and a second transistor. First ends of the first and the second transistors are coupled to a first voltage. A second end and a control end of the first transistor are respectively coupled to the first ends of the first and the second native devices. A second end and a control end of the second transistor are respectively coupled to the first ends of the second and the first native devices. A second end and a control end of the first native device are respectively coupled to an output end and an input end of the inverter. A second end and a control end of the second native device are respectively coupled to the input end and the output end of the inverter.

### BACKGROUND OF THE INVENTION

1. Field of the Invention

The invention relates to a level shifter, and more particularly to a level shifter having native devices.

2. Description of Related Art

Currently, one or more integrated circuits are disposed within electronic products. With progress towards technology, core voltages within the integrated circuits become lower and lower. Since operating voltages (i.e. input-output voltages) outside the integrated circuits are often different from the core voltages within the integrated circuits, level shifters are required for shifting levels of the input-output voltages and the core voltages.

FIG. 1 is a conventional voltage level shifting circuit 100. As indicated in FIG. 1, the voltage level shifting circuit 100 includes an inverter 150, an N channel metal oxide semiconductor (NMOS) transistor 130, an NMOS transistor 140, a P channel metal oxide semiconductor (PMOS) transistor 110, and a PMOS transistor 120. The inverter 150 is powered by a core voltage VDD. An input end of the inverter 150 receives an input signal V_{IN}. A gate of the NMOS transistor 130 is coupled to the input end of the inverter 150, a drain of the NMOS transistor 130 is coupled to a drain of the PMOS transistor 110, and a source of the NMOS transistor 130 is grounded. A gate of the NMOS transistor 140 is coupled to an output end of the inverter 150, a drain of the NMOS transistor 140 is coupled to a drain of the PMOS transistor 120, and a source of the NMOS transistor 140 is grounded. A source of the PMOS transistor 110 is coupled to an input-output voltage VDDIO, and a gate of the PMOS transistor 110 is coupled to the drain of the PMOS transistor 120. A source of the PMOS transistor 120 is coupled to the input-output voltage VDDIO, and a gate of the PMOS transistor 120 is coupled to the drain of the PMOS transistor 110. Here, the drain of the PMOS transistor 120 outputs an output signal V_{OUT}. When the input signal V_{IN} is logic high, the NMOS transistor 130 is turned on, and the NMOS transistor 140 is turned off. Since the NMOS transistor 130 is turned on, the drain of the NMOS transistor 130 is pulled down to be logic low. Besides, the PMOS transistor 120 is turned on, and thereby the drain of the PMOS transistor 120 outputting the output signal V_{OUT} is pulled up to be logic high, such that the level of the core voltage VDD is shifted to the level of the input-output voltage VDDIO. On the contrary, when the input signal V_{IN} is logic low, the PMOS transistor 110 and the NMOS transistor 140 are turned on, and the PMOS transistor 120 and the NMOS transistor 130 are turned off. Thereby, the output signal V_{OUT} is pulled down to be logic low.

However, when the input signal V_{IN} at the logic high level is converted to be at the logic low level, the gate of the PMOS transistor 120 stays at the logic low level, such that the PMOS transistor 120 is still turned on. The PMOS transistor 110 is not turned on until the pulling-down capability of the NMOS transistor 140 exceeds the pulling-up capability the PMOS transistor 120, such that the output signal V_{OUT} is pulled down to be logic low. The current of the NMOS transistor, i.e., the pulling-down capability, is positively relative to Vgs−Vt, where Vgs represents a gate-source voltage of the NMOS transistor, and Vt represents a threshold voltage of the NMOS transistor. Advanced fabrication technology brings about the reduced core voltage VDD, and therefore the value of Vgs is small when the NMOS transistor 140 (or 130) is supplied with the core voltage VDD. As a result, the NMOS transistor 140 (or 130) is not capable of pulling down the output signal V_{OUT}.

### SUMMARY OF THE INVENTION

In the invention, a level shifter including a first inverter, a first native device, a second native device, a first transistor, and a second transistor is provided. The first native device has a first end, a second end, and a control end. The second end and the control end of the first native device are respectively coupled to an output end and an input end of the first inverter. The second native device has a first end, a second end, and a control end. The second end and the control end of the second native device are respectively coupled to the input end and the output end of the first inverter. The first transistor has a first end, a second end, and a control end. The second end and the control end of the first transistor are respectively coupled to the first end of the first native device and the first end of the second native device. The second transistor has a first end, a second end, and a control end. The second end and the control end of the second transistor are respectively coupled to the first end of the second native device and the first end of the first native device. The first ends of the first and the second transistors are coupled to a first voltage.

According to an exemplary embodiment of the invention, the level shifter further includes a third transistor and a fourth transistor. The third transistor is coupled between the first transistor and the first native device. A first end of the third transistor is coupled to the second end of the first transistor, a second end of the third transistor is coupled to the first end of the first native device, and a control end of the third transistor is coupled to the input end of the first inverter. The fourth transistor is coupled between the second transistor and the second native device. A first end of the fourth transistor is coupled to the second end of the second transistor, a second end of the fourth transistor is coupled to the first end of the second native device, and a control end of the fourth transistor is coupled to the output end of the first inverter.

According to an exemplary embodiment of the invention, the level shifter further includes a second inverter, and an output end of the second inverter is coupled to the input end of the first inverter.

Based on the above, although the core voltage is low, the native devices can still be turned on for converting the output voltage according to the exemplary embodiments of the invention.

In order to make the aforementioned and other features and advantages of the invention more comprehensible, several embodiments accompanying figures are described in detail below.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention.

FIG. 1 is a conventional voltage level shifting circuit.

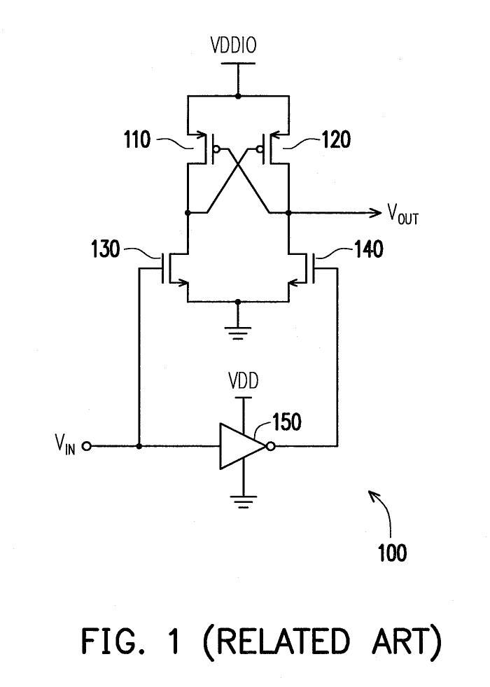

FIG. 2 is a schematic diagram illustrating circuits in a level shifter according to an exemplary embodiment of the invention.

FIG. 3 is a schematic diagram illustrating circuits in a level shifter according to another exemplary embodiment of the invention.

FIG. 4 is a schematic diagram illustrating circuits in a level shifter according to yet another exemplary embodiment of the invention.

### DESCRIPTION OF EMBODIMENTS

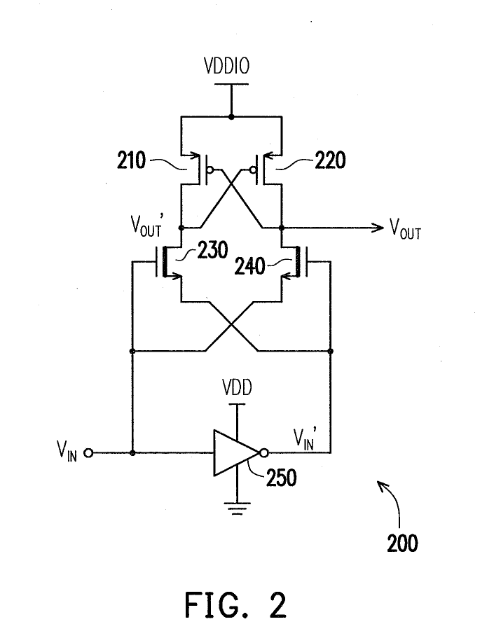

FIG. 2 is a schematic diagram illustrating circuits in a level shifter according to an exemplary embodiment of the invention. As shown in FIG. 2, the level shifter 200 includes a first transistor 210, a second transistor 220, a first native device 230, a second native device 240, and a first inverter 250. In this embodiment, the first transistor 210 and the second transistor 220 are PMOS transistors, and the first native device 230 and the second native device 240 are native NMOS transistors. However, the transistors 210 and 220 and the native devices 230 and 240 can be applied in other ways.

The first inverter 250 is powered by a second voltage (e.g. a core voltage VDD). An input end of the first inverter 250 receives an input signal V_{IN}, and an output end of the first inverter 250 outputs a signal V_{IN}′ which is an inverted signal of the input signal V_{IN}. A first end (e.g. a source) of the first transistor 210 is coupled to a first voltage (e.g. an input-output voltage VDDIO). A second end (e.g. a drain) of the first transistor 210 is coupled to a first end (e.g. a drain) of the first native device 230. A control end (e.g. a gate) of the first transistor 210 is coupled to a first end (e.g. a drain) of the second native device 240. A first end (e.g. a source) of the second transistor 220 is coupled to the input-output voltage VDDIO. A second end (e.g. a drain) of the second transistor 220 is coupled to the drain of the second native device 240. A control end (e.g. a gate) of the second transistor 220 is coupled to the drain of the first native device 230. A second end (e.g. a source) and a control end (e.g. a gate) of the first native device 230 are respectively coupled to an output end and an input end of the first inverter 250. A second end (e.g. a source) and a control end (e.g. a gate) of the second native device 240 are respectively coupled to the input end and the output end of the first inverter 250. A drain voltage of the second transistor 220 serves as an output signal V_{OUT} of the level shifter 200, and a drain voltage of the first transistor 210 can serve as an output signal V_{OUT}′ which is an inverted signal of the output signal V_{OUT}. The input-output voltage VDDIO is higher than the core voltage VDD.

In this embodiment, the native devices 230 and 240 are the native NMOS transistors having negative threshold voltages. A current passing through the native devices 230 and 240, i.e. the pulling-down capability, is positively relative to Vgs−(−Vt), where Vgs represents the gate-source voltage of the native devices 230 and 240, and −Vt represents a threshold voltage of the native devices 230 and 240. Therefore, when the native device 230 (or 240) is supplied with the core voltage VDD, the current of the native device 240 (or 230), i.e., the pulling-down capability, is sufficient to pull down the output signal V_{OUT} (or the inverted output signal V_{OUT}′), even through the value of Vgs is small because the core voltage VDD is low.

In the present embodiment, the native devices 230 and 240 are already on, and therefore the native devices 230 and 240 can be completely turned off by applying the negative voltage Vgs to the native devices 230 and 240. As such, in the embodiment, the gate and the source of the first native device 230 are respectively coupled to the input end and the output end of the first inverter 250, and the gate and the source of the second native device 240 are respectively coupled to the output end and the input end of the first inverter 250. When the gate of the second native device 240 is logic low (e.g. at a ground level), the source of the second native device 240 is definitely logic high (e.g. the core voltage VDD). Hence, the negative voltage Vgs is generated between the gate and the source of the second native device 240 so as to turn off the second native device 240. The principle of operating the first native device 230 is similar to that of the second native device 240, and therefore no further description is provided hereinafter.

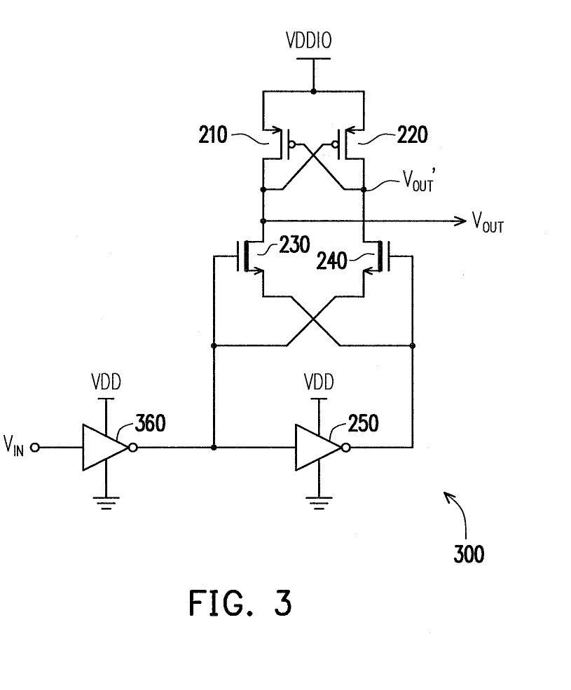

People having ordinary skill in the art can implement the invention by referring to the above embodiments. However, the implementation of the invention is not limited to the above. Based on actual design demands, people having ordinary skill in the art can modify the above embodiments. For instance, please refer to FIG. 3, which is a schematic diagram illustrating circuits in a level shifter 300 according to another exemplary embodiment of the invention. The level shifter 300 is similar to the level shifter 200 shown in FIG. 2, and the embodiments of the level shifter 200 can be incorporated herein by reference. The differences between the level shifters 200 and 300 lie in that the level shifter 300 further includes a second inverter 360, and the drain voltage of the first transistor 210 serves as the output signal V_{OUT} of the level shifter 300. The drain voltage of the second transistor 220 is the inverted output signal V_{OUT}′.

As indicated in FIG. 3, an input end of the second inverter 360 receives the input signal V_{IN}, and an output end of the second inverter 360 is coupled to the input end of the first inverter 250. Here, the first inverter 250 and the second inverter 360 are powered by the core voltage VDD.

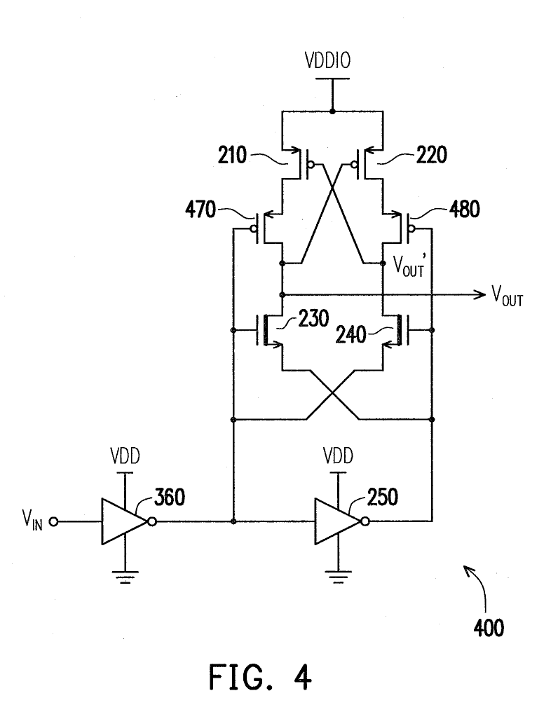

FIG. 4 is a schematic diagram illustrating circuits in a level shifter 400 according to yet another exemplary embodiment of the invention. The level shifter 400 is similar to the level shifter 200 shown in FIG. 2 and the level shifter 300 shown in FIG. 3, and the embodiments of the level shifters 200 and 300 can be incorporated herein by reference. The differences between the level shifters 200, 300, and 400 lie in that the level shifter 400 further includes a second inverter 360, a third transistor 470, and a fourth transistor 480.

In this embodiment, the third transistor 470 and the fourth transistor 480 are PMOS transistors, which is not limited in the invention.

The third transistor 470 is coupled between the first transistor 210 and the first native device 230. Here, a first end (e.g. a source) of the third transistor 470 is coupled to the drain of the first transistor 210, a second end (e.g. a drain) of the third transistor 470 is coupled to the drain of the first native device 230, and a control end (e.g. a gate) of the third transistor 470 is coupled to the input end of the first inverter 250. The fourth transistor 480 is coupled between the second transistor 220 and the second native device 240. Here, a first end (e.g. a source) of the fourth transistor 480 is coupled to the drain of the second transistor 220, a second end (e.g. a drain) of the fourth transistor 480 is coupled to the drain of the second native device 240, and a control end (e.g. a gate) of the fourth transistor 480 is coupled to the output end of the first inverter 250. In the level shifter 400, a drain voltage of the third transistor 470, i.e., the drain voltage of the first native device 230, serves as the output signal V_{OUT}. A drain voltage of the fourth transistor 480 is the inverted output signal V_{OUT}′.

In light of the foregoing, the pulling-down capability of the output signal V_{OUT} (or the inverted output signal V_{OUT}′) can be enhanced by utilizing the native devices 230 and 240 having the low threshold voltages or the negative threshold voltages. Consequently, even though the core voltage is applied in the advanced manufacturing technology according to the above embodiments, the level shifter of the present embodiments can still operate in a normal manner to convert the output voltage.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A level shifter, comprising:
a first inverter;
a first native device having a first end, a second end coupled to an output end of the first inverter, and a control end coupled to an input end of the first inverter;
a second native device having a first end, a second end coupled to the input end of the first inverter, and a control end coupled to the output end of the first inverter; a first transistor having a first end coupled to a first voltage, a second end coupled to the first end of the first native device, and a control end coupled to the first end of the second native device; and
a second transistor having a first end coupled to the first voltage, a second end coupled to the first end of the second native device, and a control end coupled to the first end of the first native device.

2. The level shifter as claimed in claim 1, wherein the first inverter is powered by a second voltage.

3. The level shifter as claimed in claim 2, wherein the first voltage is an input-output voltage, and the second voltage is a core voltage.

4. The level shifter as claimed in claim 3, wherein the input-output voltage is higher than the core voltage.

5. The level shifter as claimed in claim 1, wherein the first transistor and the second transistor are P channel metal oxide semiconductor (PMOS) transistors.

6. The level shifter as claimed in claim 1, wherein the first native device and the second native device are native N channel metal oxide semiconductor transistors.

7. The level shifter as claimed in claim 1, further comprising:
a third transistor coupled between the first transistor and the first native device, wherein a first end of the third transistor is coupled to the second end of the first transistor, a second end of the third transistor is coupled to the first end of the first native device, and a control end of the third transistor is coupled to the input end of the first inverter; and
a fourth transistor coupled between the second transistor and the second native device, wherein a first end of the fourth transistor is coupled to the second end of the second transistor, a second end of the fourth transistor is coupled to the first end of the second native device, and a control end of the fourth transistor is coupled to the output end of the first inverter.

8. The level shifter as claimed in claim 7, wherein the first transistor, the second transistor, the third transistor, and the fourth transistor are PMOS transistors.

9. The level shifter as claimed in claim 1, further comprising a second inverter, wherein an output end of the second inverter is coupled to the input end of the first inverter.

10. The level shifter as claimed in claim 9, wherein the first inverter and the second inverter are powered by a second voltage.
